(19) United States
(12) Patent Application Publication
(10) Pub. No.: US 2025/0113535 A1
(43) Pub. Date: Apr. 3, 2025

(54) SEMICONDUCTOR DEVICE

(71) Applicant: Japan Display Inc., Tokyo (JP)

(72) Inventors: Hajime WATAKABE, TOKYO (JP); Masashi TSUBUKU, TOKYO (JP); Toshinari SASAKI, TOKYO (JP); Takaya TAMARU, TOKYO (JP); Marina MOCHIZUKI, TOKYO (JP); Masahiro WATABE, TOKYO (JP)

(73) Assignee: Japan Display Inc., Tokyo (JP)

(21) Appl. No.: 18/895,467

(22) Filed: Sep. 25, 2024

(30) Foreign Application Priority Data
Sep. 29, 2023 (JP) 2023-170532

(51) Int. Cl. H01L 29/786

(52) U.S. Cl. CPC H10D 30/6723; H10D 30/6755

(57) ABSTRACT

A semiconductor device includes a light shielding layer, a first silicon nitride insulating layer in contact with the light shielding layer with a first interface, a first silicon oxide insulating layer in contact with the first silicon nitride layer with a second interface, and an oxide semiconductor layer over the first silicon oxide insulating layer. The first silicon oxide insulating layer is in contact with the second silicon oxide insulating layer. A thickness t of the first silicon nitride layer satisfies a condition in which light reflected at the first interface and light reflected at the second interface weaken each other when light having a wavelength of 450 nm is incident on the first silicon nitride insulating layer at an angle of 60 degrees from a normal direction of the second interface.

### CROSS-REFERENCE TO RELATED APPLICATIONS

This application claims the benefit of priority to Japanese Patent Application No. 2023-170532, filed on Sep. 29, 2023, the entire contents of which are incorporated herein by reference.

### FIELD

An embodiment of the present invention relates to a semiconductor device using an oxide semiconductor film as a channel.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication Nos. 2021-141338, 2014-099601, 2021-153196, 2018-006730, 2016-184771, and 2021-108405). The semiconductor device including an oxide semiconductor film can be fabricated with a simple structure and low-temperature process, similar to a semiconductor device including an amorphous silicon film. Further, the semiconductor device including an oxide semiconductor film is known to have a higher field effect mobility than the semiconductor device including an amorphous silicon film.

### SUMMARY

A semiconductor device according to an embodiment of the present invention includes a light shielding layer, a first silicon nitride insulating layer over and in contact with the light shielding layer, a first silicon oxide insulating layer over and in contact with the first silicon nitride layer, an oxide semiconductor layer including a channel region, a source region, and a drain region over the first silicon oxide insulating layer, a second silicon oxide insulating layer over the oxide semiconductor layer, a gate electrode over the second silicon oxide insulating layer, and a second silicon nitride insulating layer over the gate electrode. A first interface is formed between the light shielding layer and the first silicon nitride insulating layer. A second interface is formed between the first silicon nitride insulating layer and the first silicon oxide insulating layer. In a plan view, the entire channel region overlaps the light shielding layer. The first silicon oxide insulating layer is in contact with the second silicon oxide insulating layer. A thickness t of the first silicon nitride layer satisfies a condition in which first light reflected at the first interface and second light reflected at the second interface weaken each other when light having a wavelength of 450 nm is incident on the first silicon nitride insulating layer at an angle of 60 degrees from a normal direction of the second interface.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a flowchart showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a schematic cross-sectional view showing a method for manufacturing a semiconductor device according to an embodiment of the present invention.

FIG. 13 is a schematic cross-sectional view showing a method for manufacturing a semiconductor device according to an embodiment of the present invention.

FIG. 14 is a schematic cross-sectional view showing a method for manufacturing a semiconductor device according to an embodiment of the present invention.

FIG. 15 is a schematic cross-sectional view showing a method for manufacturing a semiconductor device according to an embodiment of the present invention.

FIG. 16 is a schematic cross-sectional view showing a method for manufacturing a semiconductor device according to an embodiment of the present invention.

FIG. 17 is a graph showing a variation amount in a threshold voltage in an NBTIS test with respect to a thickness of a first silicon nitride insulating layer and a thickness of a first silicon oxide insulating layer.

FIG. 18 is a simulation result of a reflectance showing an incidence angle dependence of a first silicon nitride insulating layer.

### DESCRIPTION OF EMBODIMENTS

Since an oxide semiconductor film transmits light in the visible light region, a semiconductor device including the oxide semiconductor film has less photodegradation than a semiconductor device including a silicon semiconductor film. However, it is desired to further suppress photodegradation in a semiconductor device including an oxide semiconductor film.

An embodiment of the present invention can provide a semiconductor device in which photodegradation is suppressed.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode above a semiconductor device.” On the other hand, the expression “a pixel electrode vertically over a semiconductor device” means a positional relationship in which the semiconductor device and the pixel electrode overlap in a plan view. In addition, a plan view refers to viewing from a direction perpendicular to a surface of the substrate.

In the present specification and the like, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the terms “film” and “layer” can be optionally interchanged with one another.

In addition, the following embodiments can be combined with each other as long as there is no technical contradiction.

### First Embodiment

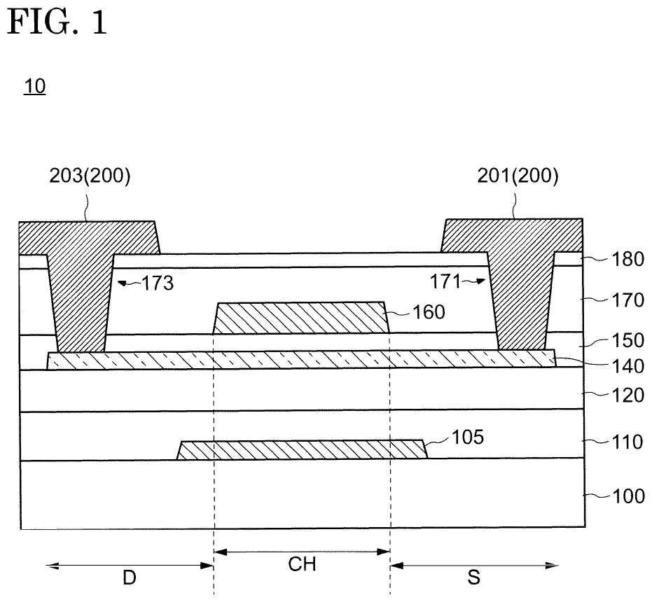

A semiconductor device 10 according to an embodiment of the present invention is described with reference to FIGS. 1 to 10.

### [1. Configuration of Semiconductor Device 10]

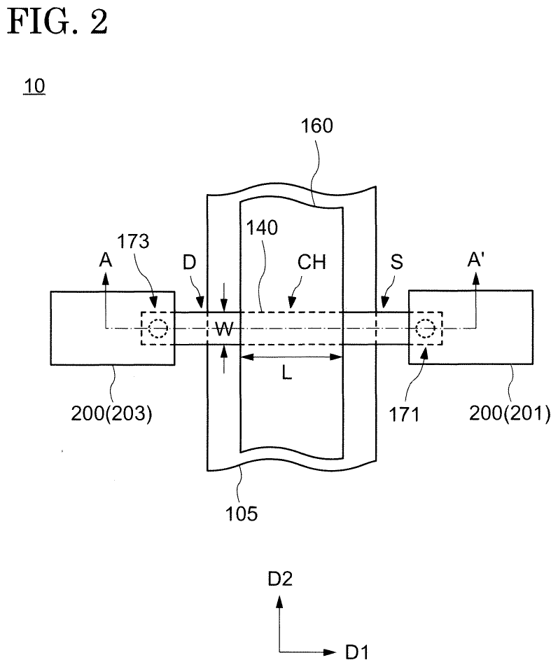

A configuration of a semiconductor device 10 according to an embodiment of the present invention is described with reference to FIGS. 1 and 2. FIG. 1 is a schematic cross-sectional view showing a configuration of the semiconductor device 10 according to an embodiment of the present invention. FIG. 2 is a schematic plan view showing the configuration of the semiconductor device according to an embodiment of the present invention. Specifically, FIG. 1 is a cross-sectional view cut along a line A-A′ in FIG. 2.

As shown in FIG. 1, the semiconductor device 10 includes a substrate 100, a light shielding layer 105, a first silicon nitride insulating layer 110, a first silicon oxide insulating layer 120, an oxide semiconductor layer 140, a second silicon oxide insulating layer 150, a gate electrode 160, a second silicon nitride insulating layer 170, a third silicon oxide insulating layer 180, a source electrode 201, and a drain electrode 203. The light shielding layer 105 is provided on the substrate 100. The first silicon nitride insulating layer 110 is provided on the substrate 100 so as to cover an upper surface and an edge surface of the light shielding layer 105. The first silicon oxide insulating layer 120 is provided on the first silicon nitride insulating layer 110. The oxide semiconductor layer 140 is provided on the first silicon oxide insulating layer 120. The second silicon oxide insulating layer 150 is provided on the first silicon oxide insulating layer 120 so as to cover an upper surface and an edge surface of the oxide semiconductor layer 140. The gate electrode 160 is provided on the second silicon oxide insulating layer 150 so as to overlap the oxide semiconductor layer 140. The second silicon nitride insulating layer 170 is provided on the second silicon oxide insulating layer 150 so as to cover an upper surface and an edge surface of the gate electrode 160. The third silicon oxide insulating layer 180 is provided on the second silicon nitride insulating layer 170. The second silicon oxide insulating layer 150, the second silicon nitride insulating layer 170, and the third silicon oxide insulating layer 180 are provided with openings 171 and 173 through which a part of the upper surface of the oxide semiconductor layer 140 is exposed. The source electrode 201 is provided on the third silicon oxide insulating layer 180 and inside the opening 171, and is in contact with the oxide semiconductor layer 140. Similarly, the drain electrode 203 is provided on the third silicon oxide insulating layer 180 and inside the opening 173, and is in contact with the oxide semiconductor layer 140. In addition, hereinafter, when the source electrode 201 and the drain electrode 203 are not particularly distinguished, they may be collectively referred to as a source/drain electrode 200.

The oxide semiconductor layer 140 is divided into a source region S, a drain region D, and a channel region CH based on the gate electrode 160. That is, the oxide semiconductor layer 140 includes the channel region CH which overlaps the gate electrode 160 and the source region S and the drain region D which do not overlap the gate electrode 160. In the thickness direction of the oxide semiconductor layer 140, an edge portion of the channel region CH substantially coincides with an edge portion of the gate electrode 160. The channel region CH has properties of a semiconductor. Each of the source region S and the drain region D has properties of a conductor. Therefore, the electrical conductivities of the source region S and the drain region D are greater than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the semiconductor device 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH from the substrate 100 side. A metal material can be used for the light shielding layer 105. Specifically, aluminum (Al), copper (Cu), titanium (Ti), molybdenum (Mo), or tungsten (W), or alloys thereof can be used for the light shielding layer 105. For example, although an alloy used for the light shielding layer 105 is molybdenum tungsten (MoW), the alloy is not limited thereto.

The first silicon nitride insulating layer 110, the first silicon oxide insulating layer 120, the second silicon nitride insulating layer 170, and the third silicon oxide insulating layer 180 can prevent the diffusion of impurities into the oxide semiconductor layer 140. Specifically, the first silicon nitride insulating layer 110 and the first silicon oxide insulating layer 120 can prevent the diffusion of impurities contained in the substrate 100, and the second silicon nitride insulating layer 170 and the third silicon oxide insulating layer 180 can prevent the diffusion of impurities (e.g., water, etc.) entering from the outside. For example, silicon nitride (SiNₓ), silicon nitride oxide (SiNₓO_{y}), or the like can be used for the first silicon nitride insulating layer 110 and the second silicon 170. Further, silicon oxide (SiOₓ), silicon oxynitride (SiOₓN_{y}), or the like can be used for the first silicon oxide insulating layer 120 and the third silicon oxide insulating layer 180. Here, silicon nitride oxide (SiNₓO_{y}) is a silicon compound containing a smaller proportion of oxygen than nitrogen (x>y). Further, silicon oxynitride (SiOₓN_{y}) is a silicon compound containing a smaller proportion (x>y) of nitrogen (N) than oxygen (O).

Each of the first silicon nitride insulating layer 110, the first silicon oxide insulating layer 120, the second silicon nitride insulating layer 170, and the third silicon oxide insulating layer 180 may have a planarizing function. Further, the first silicon oxide insulating layer 120 may have a function of releasing oxygen by a heat treatment. When the first silicon oxide insulating layer 120 has a function of releasing oxygen by a heat treatment, oxygen is released from the first silicon oxide insulating layer 120 by a heat treatment performed in a manufacturing process of the semiconductor device 10, so that the released oxygen can be supplied to the oxide semiconductor layer 140.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys thereof can be used for each of the gate electrode 160, the source electrode 201, and the drain electrode 203. Each of the gate electrode 160, source electrode 201, and drain electrode 203 may have a single layer structure or a laminated structure.

The second silicon oxide insulating layer 150 functions as a gate insulating layer. For example, silicon oxide (SiOₓ), silicon oxynitride (SiOₓN_{y}), or the like can be used for the second silicon oxide insulating layer 150. It is preferable that the second silicon oxide insulating layer 150 has a composition close to a stoichiometric ratio. Further, it is preferable that the second silicon oxide insulating layer 150 has few defects. Specifically, it is preferable that the second silicon oxide insulating layer 150 has no defects observed when evaluated by an electron spin resonance (ESR).

An oxide semiconductor containing two or more metal elements including indium (In), gallium (Ga), zinc (Zn), aluminum (Al), hafnium (Hf), yttrium (Y), zirconium (Zr), and lanthanoids are used for the oxide semiconductor layer 140. The oxide semiconductor layer 140 may have an amorphous structure or a polycrystalline structure. However, it is preferable that the oxide semiconductor layer 140 has a polycrystalline structure in order to improve electrical characteristics.

When the oxide semiconductor layer 140 has a polycrystalline structure, it is preferable that an oxide semiconductor in which the atomic ratio of indium to all metal elements is greater than or equal to 50% is used for the oxide semiconductor layer 140. When the ratio of the indium is increased, the oxide semiconductor layer 140 is easily crystallized. Further, it is preferable that gallium is contained as a metal element other than indium. Gallium belongs to the same group 13 elements as indium. Therefore, the oxide semiconductor layer 140 has a polycrystalline structure without gallium inhibiting the crystallinity of the oxide semiconductor layer 140.

Although a detailed method for manufacturing the oxide semiconductor layer 140 is described in a method for manufacturing the semiconductor device, which is described later, the oxide semiconductor layer 140 can be formed using a sputtering method. The composition of the oxide semiconductor layer 140 formed by sputtering depends on the composition of the sputtering target. When the oxide semiconductor layer 140 has a polycrystalline structure, the composition of the oxide semiconductor layer 140 is substantially identical to the composition of the sputtering target. In this case, the composition of the metal elements in the oxide semiconductor layer 140 can be specified based on the composition of the metal elements in the sputtering target. Further, when the oxide semiconductor layer 140 has a polycrystalline structure, the composition of the oxide semiconductor layer 140 may be specified by an X-ray diffraction (XRD) method. Specifically, the composition of the metal elements in the oxide semiconductor layer 140 can be specified based on the crystal structure and lattice constant of the oxide semiconductor layer 140 obtained by the XRD method. Furthermore, the composition of the metal elements of the oxide semiconductor layer 140 can also be identified using fluorescent X-ray analysis, electron probe microanalyzer (EPMA) analysis, or the like. In addition, oxygen contained in the oxide semiconductor layer 140 is not limited to this because oxygen changes depending on the sputtering process conditions and the like.

Although the oxide semiconductor layer 140 may have an amorphous structure or a polycrystalline structure as described above, it is preferable that the oxide semiconductor layer 140 has a polycrystalline structure. An oxide semiconductor having a polycrystalline structure can be manufactured using a poly-crystalline oxide semiconductor (Poly-OS) technology. Hereinafter, the oxide semiconductor having a polycrystalline structure may be described as Poly-OS when distinguished from an oxide semiconductor having an amorphous structure.

Although the configuration of the semiconductor device 10 is described above, the semiconductor device 10 described above is a so-called top-gate transistor. Various modifications can be applied to the semiconductor device 10. For example, when the light shielding layer 105 has conductivity, the semiconductor device 10 may have a configuration in which the light shielding layer 105 functions as a gate electrode, and the first silicon nitride insulating layer 110 and the first silicon oxide insulating layer 120 function as gate insulating layers. In this case, the semiconductor device 10 is a so-called dual-gate transistor. Further, when the light shielding layer 105 has conductivity, the light shielding layer 105 may be a floating electrode and may be connected to the source electrode 201. Furthermore, the semiconductor device 10 may be a so-called bottom-gate transistor in which the light shielding layer 105 functions as a main gate electrode.

### [2. Manufacturing Method of Semiconductor Device 10]

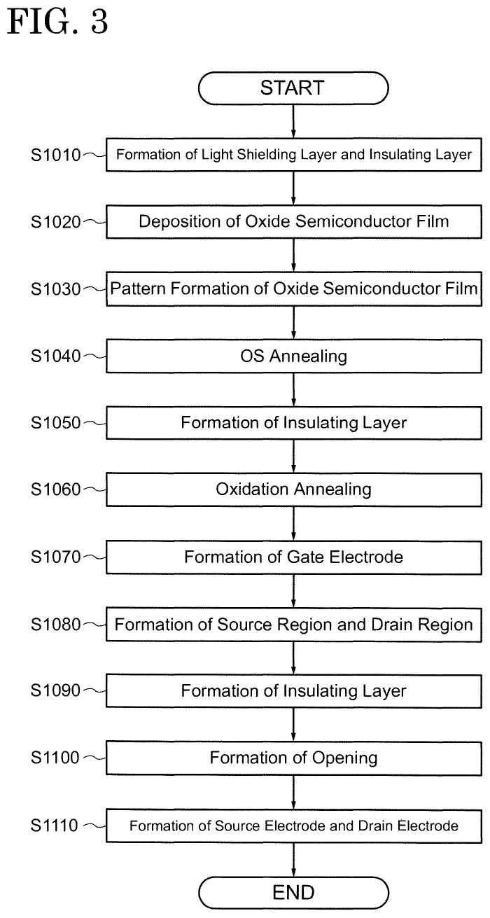

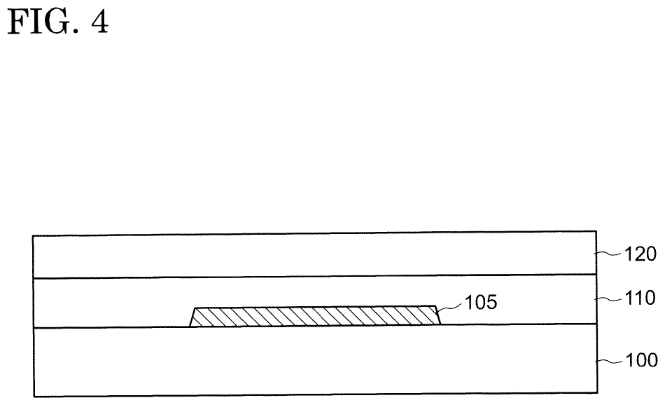

A method for manufacturing the semiconductor device 10 according to an embodiment of the present invention is described with reference to FIGS. 3 to 10. FIG. 3 is a flowchart showing the method for manufacturing the semiconductor device 10 according to an embodiment of the present invention. FIGS. 4 to 10 are schematic cross-sectional views showing the method for manufacturing the semiconductor device 10 according to an embodiment of the present invention.

As shown in FIG. 3, the method for manufacturing the semiconductor device 10 includes steps S1010 to S1110. Although steps S1010 to S1110 are described in order below, the order of the steps may be interchanged in the method for manufacturing the semiconductor device 10. Further, the method for manufacturing the semiconductor device 10 may include additional steps.

In step S1010, the light shielding layer 105 having a predetermined pattern is formed on the substrate 100. The light shielding layer 105 is patterned using a photolithography method. The first silicon nitride insulating layer 110 and the first silicon oxide insulating layer 120 are formed on the light shielding layer 105 (see FIG. 4). The first silicon nitride insulating layer 110 and the first silicon oxide insulating layer 120 are deposited using a CVD method. For example, silicon nitride and silicon oxide are deposited for the first silicon nitride insulating layer 110 and the first silicon oxide insulating layer 120, respectively. When silicon nitride is used for the first silicon nitride insulating layer 110, the first silicon nitride insulating layer 110 can block impurities diffused from the substrate 100 side to the oxide semiconductor layer 140. When silicon oxide is used for the first silicon oxide insulating layer 120, the first silicon oxide insulating layer 120 can release oxygen by a heat treatment.

The light incident on the first silicon nitride insulating layer 110 is reflected not only at the interface between the light shielding layer 105 and the first silicon nitride insulating layer 110 (hereinafter, referred to as the “first interface”), but also at the interface between the first silicon nitride insulating layer 110 and the first silicon oxide insulating layer 120 (hereinafter, referred to as the “second interface”). Therefore, when the light intensified by the interference effect is incident on the channel region of the oxide semiconductor layer 140, the photodegradation of the oxide semiconductor layer 140 is promoted. Therefore, in the semiconductor device 10, the thickness of the first silicon nitride insulating layer 110 is adjusted so as to satisfy the condition that the light reflected at the first interface and the light reflected at the second interface weaken each other when light with a wavelength of 450 nm is incident on the first silicon nitride insulating layer at an angle of 60 degrees from the normal direction of the second interface. As a result, the photodegradation of the oxide semiconductor layer 140 can be suppressed. For example, the thickness t (nm) of the first silicon nitride insulating layer 110 is adjusted to satisfy the following equation: t=150 (a−1)+b (where a is a natural number and b is a constant), where the constant b is, for example, 75±12.5.

There is no particular limitation on the thickness of the first silicon oxide insulating layer 120. For example, the thickness of the first silicon oxide insulating layer 120 is greater than the thickness of the first silicon nitride insulating layer 110.

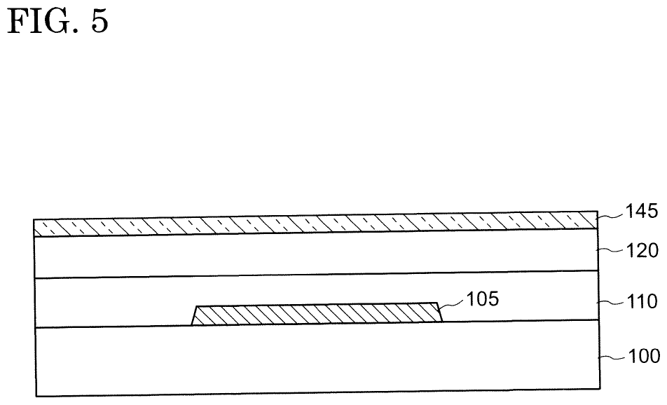

In step S1020, the oxide semiconductor film 145 is deposited on the first silicon oxide insulating layer 120 (see FIG. 5). The oxide semiconductor film 145 is formed using a sputtering method. The thickness of the oxide semiconductor film 145 is, for example, 10 nm to 100 nm, preferably 15 nm to 70 nm, and more preferably 15 nm to 40 nm.

The oxide semiconductor film 145 in step S1030 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is formed by the sputtering method, the oxide semiconductor film 145 is deposited while controlling the temperature of the object to be deposited (the substrate 100 and the layers formed thereon) to less than or equal to 100° C., preferably less than or equal to 80° C., and preferably less than or equal to 50° C. Further, the oxide semiconductor film 145 is deposited under a condition of low oxygen partial pressure. The oxygen partial pressure is greater than or equal to 2% and less than or equal to 20%, preferably greater than or equal to 3% and less than or equal to 15%, and more preferably greater than or equal to 3% and less than or equal to 10%.

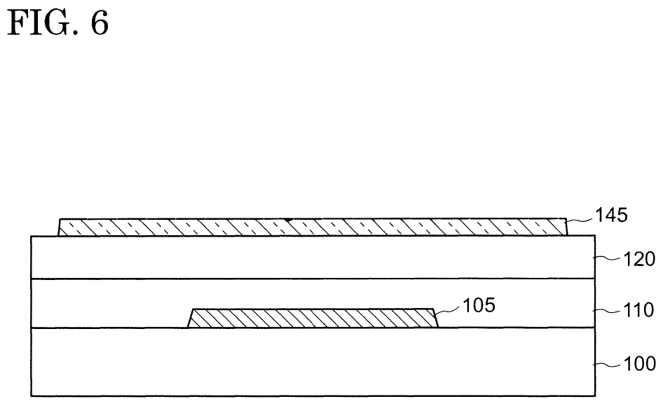

In step S1030, the oxide semiconductor film 145 is patterned (see FIG. 6). The oxide semiconductor film 145 is patterned using a photolithography method. The oxide semiconductor film 145 may be etched using wet etching or dry etching. In the wet etching, an acidic etching solution may be used. For example, oxalic acid, PAN, sulfuric acid, a hydrogen peroxide solution, or hydrofluoric acid may be used as the etching solution.

In step S1050, a heat treatment is performed on the oxide semiconductor film 145. Hereinafter, the heat treatment performed in step S1050 is referred to as “OS annealing”. In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. Further, the holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor layer 140 containing Poly-OS) by the OS annealing.

The oxide semiconductor layer 140 containing Poly-OS has excellent etching resistance. Specifically, the etching rate of the oxide semiconductor layer 140 is very small when the oxide semiconductor layer 140 is etched using an etching solution for wet etching. This means that the oxide semiconductor layer 140 is hardly etched by the etching solution. The etching rate when the oxide semiconductor layer 140 is etched using an etching solution containing phosphoric acid as a main component at 40° C. (hereinafter, referred to as a “mixed acid etching solution”) is less than 3 nm/min, less than 2 nm/min, or less than 1 nm/min. The ratio of phosphoric acid in the mixed acid etching solution is greater than or equal to 50%, greater than or equal to 60%, or greater than or equal to 70%. The mixed acid etching solution may contain acetic acid and nitric acid in addition to phosphoric acid. In addition, when an oxide semiconductor film not containing Poly-OS, for example, the oxide semiconductor film having an amorphous structure before the heat treatment, is etched using the mixed acid etching solution at 40° C., the etching rate of the oxide semiconductor film is greater than or equal to 100 nm/min. The etching rate when the oxide semiconductor layer 140 is etched using 0.5% of a hydrofluoric acid solution at room temperature is less than 5 nm/min, less than 4 nm/min, or less than 3 nm/min. When the oxide semiconductor film not containing Poly-OS is etched using 0.5% of the hydrofluoric acid solution at room temperature, the etching rate of the oxide semiconductor film is greater than or equal to 15 nm/min. Here, “40° C.” refers to 40±5° C. and may be the temperature of the etching solution or the set temperature of the etching solution. Further, “room temperature” refers to 25±5° C.

Examples of etching rates of the oxide semiconductor layer 140 are shown in Table 1. Table 1 shows the etching rates of each of the prepared samples with respect to a mixed acid etching solution (“Mixed Acid AT-2F” manufactured by Rasa Kogyo Co., Ltd., in which the ratio of phosphoric acid in the mixed acid etching solution is 65%) and 0.5% of a hydrofluoric acid solution. When each sample was etched, the temperature of the mixed acid etching solution was 40° C., and the temperature of 0.5% of the hydrofluoric acid solution was room temperature. In Table 1, Sample 1 is the oxide semiconductor layer 140 containing Poly-OS, Sample 2 is an oxide semiconductor film having an amorphous structure before the heat treatment, and Sample 3 is an oxide semiconductor film containing indium gallium zinc oxide (IGZO) in which the ratio of indium is less than 50%.

TABLE 1

| | |
|---|---|
| Mixed acid | 0.5% of |
| etching | hydrofluoric |
| solution | acid solution |

| | | | | |
|---|---|---|---|---|
| Sample 1 | <0.1 | nm/min | <2 | nm/min |
| Sample 2 | 111 | nm/min | >18 | nm/min |

| | | | |
|---|---|---|---|
| Sample 3 | 162 | nm/min | — |

As shown in Table 1, Sample 1 (oxide semiconductor layer 140 containing Poly-OS) is hardly etched using the mixed acid etching solution, and is etched at only 2 nm/min at most even when 0.5% of the hydrofluoric acid solution is used. When etching using the mixed acid etching solution, the etching rate of Sample 1 is less than or equal to 1/100 of the etching rate of Sample 2 (oxide semiconductor film having an amorphous structure before the heat treatment). When etching using 0.5% of the hydrofluoric acid solution, the etching rate of Sample 1 is less than or equal to approximately 1/10 of the etching rate of Sample 2. Further, when etching using the mixed acid etching solution, the etching rate of Sample 1 is less than or equal to 1/100 of the etching rate of Sample 3 (oxide semiconductor film containing IGZO in which the ratio of indium is less than 50%). That is, Sample 1 has significantly better etching resistance than Samples 2 and 3.

Such excellent etching resistance of the oxide semiconductor layer OS containing Poly-OS is a characteristic that cannot be obtained with the conventional oxide semiconductor having a polycrystalline structure, which is manufactured by a process lower than or equal to 500° C. Although the detailed mechanism of the excellent etching resistance of the oxide semiconductor layer 140 containing Poly-OS is unclear, it is considered that the Poly-OS has a polycrystalline structure different from that of a conventional oxide semiconductor.

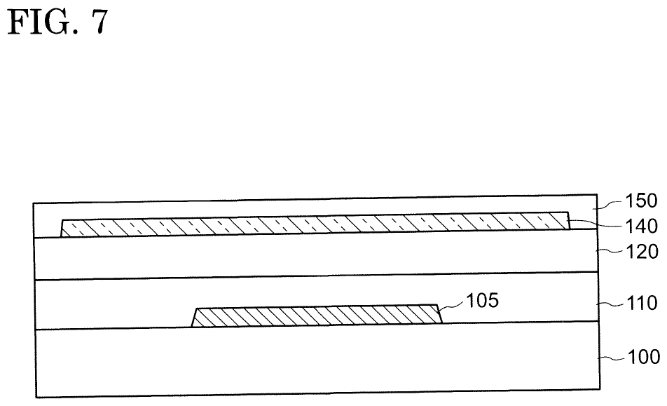

In step S1050, the second silicon oxide insulating layer 150 is formed on the oxide semiconductor layer 140 (see FIG. 7). The second silicon oxide insulating layer 150 is deposited using a CVD method. For example, silicon oxide is deposited for the second silicon oxide insulating layer 150. In order to reduce defects in the second silicon oxide insulating layer 150, the second silicon oxide insulating layer 150 may be deposited at a film deposition temperature higher than or equal to 350° C. The thickness of the second silicon oxide insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After depositing the second silicon oxide insulating layer 150, a process of introducing oxygen into a part of the second silicon oxide insulating layer 150 may be performed.

The second silicon oxide insulating layer 150 is in contact with the first silicon oxide insulating layer 120. It is preferable that the total thickness of the first silicon oxide insulating layer 120 and the second silicon oxide insulating layer 150 is greater than the thickness of the first silicon nitride insulating layer 110.

In step S1060, a heat treatment is performed on the oxide semiconductor layer 140. Hereinafter, the heat treatment performed in step S1060 is referred to as “oxidation annealing.” When the second silicon oxide insulating layer 150 is formed on the oxide semiconductor layer 140, many oxygen deficiencies are generated on the upper surface and the side surfaces of the oxide semiconductor layer 140. When the oxidation annealing is performed, oxygen is supplied from the first silicon oxide insulating layer 120 and the second silicon oxide insulating layer 150 to the oxide semiconductor layer 140, so that the oxygen deficiencies are repaired.

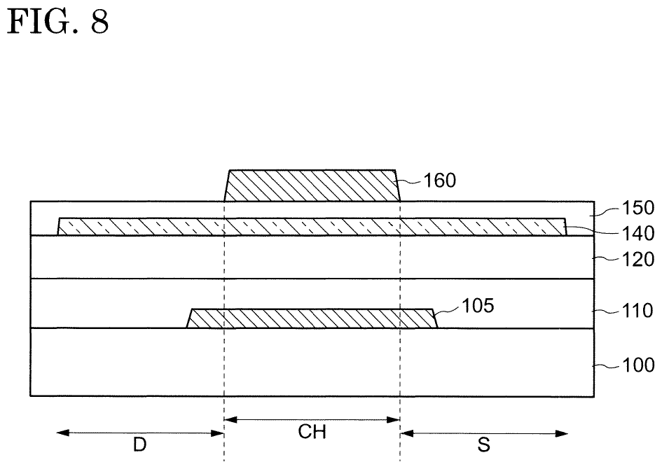

In step S1070, the gate electrode 160 having a predetermined pattern is formed on the second silicon oxide insulating layer 150 (see FIG. 8). The gate electrode 160 is formed using a sputtering method or an atomic layer deposition method, and the gate electrode 160 is patterned using a photolithography method.

In step S1080, the source region S and the drain region D are formed in the oxide semiconductor layer 140 (see FIG. 8). The source region S and the drain region D are formed by ion implantation. Specifically, impurities are implanted into the oxide semiconductor layer 140 through the second silicon oxide insulating layer 150 using the gate electrode 160 as a mask. For example, argon (Ar), phosphorus (P), boron (B), or the like is used as the implanted impurity. In the source region S and the drain region D that do not overlap the gate electrode 160, oxygen deficiencies are generated by ion implantation, and hydrogen is trapped in the generated oxygen deficiencies. As a result, the resistance of the source region S and the drain region D decreases. On the other hand, in the channel region that overlaps the gate electrode 160, impurities are not implanted, so that oxygen deficiencies are not generated and the resistance of the channel region CH does not decrease.

In the semiconductor device 10, since impurities are implanted into the oxide semiconductor layer 140 through the second silicon oxide insulating layer 150, the second silicon oxide insulating layer 150 may also contain impurities such as argon (Ar), phosphorus (P), or boron (B).

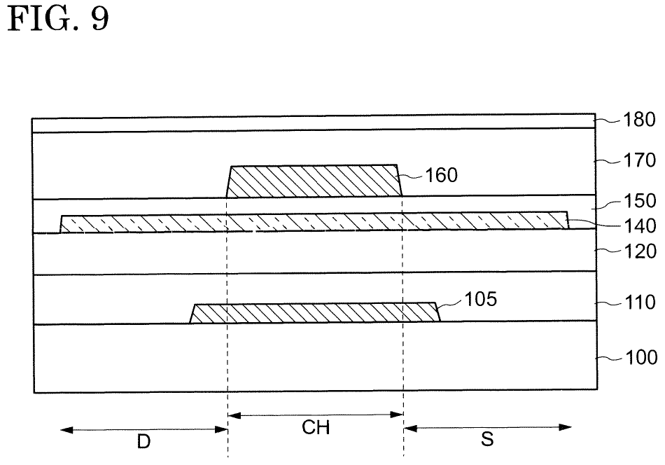

In step S1090, the second silicon nitride insulating layer 170 and the third silicon oxide insulating layer 180 are formed on the second silicon oxide insulating layer 150 and the gate electrode 160 (see FIG. 9). The second silicon nitride insulating layer 170 and the third silicon oxide insulating layer 180 are deposited using a CVD method. For example, silicon oxide and silicon nitride are deposited for the second silicon nitride insulating layer 170 and the third silicon oxide insulating layer 180, respectively. The thickness of the second silicon nitride insulating layer 170 is greater than or equal to 50 nm and less than or equal to 500 nm. The thickness of the third silicon oxide insulating layer 180 is also greater than or equal to 50 nm and less than or equal to 500 nm.

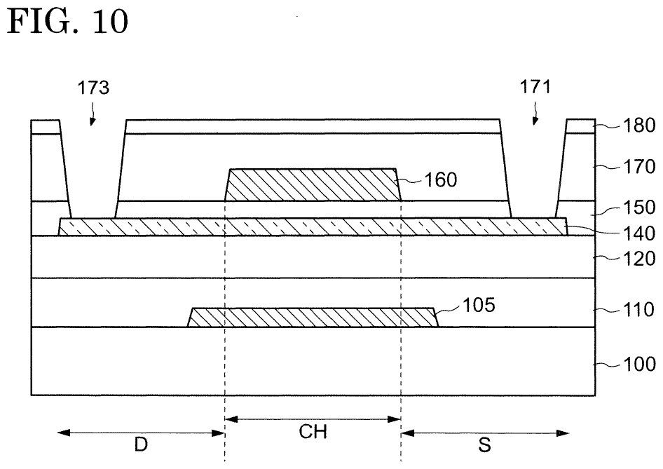

In step S1100, the openings 171 and 173 are formed in the second silicon oxide insulating layer 150, the second silicon nitride insulating layer 170, and the third silicon oxide insulating layer 180 (see FIG. 10). When the openings 171 and 173 are formed, the source region S and the drain region D of the oxide semiconductor layer 140 are exposed in the openings 171 and 173.

In step S1110, the source electrode 201 is formed on the third silicon oxide insulating layer 180 and inside the opening 171, and the drain electrode 203 is formed on the third silicon oxide insulating layer 180 and inside the opening 173. The source electrode 201 and the drain electrode 203 are formed in the same layer. Specifically, the source electrode 201 and the drain electrode 203 are formed by patterning a single conductive film to be deposited. The semiconductor device 10 shown in FIG. 1 is manufactured through the above steps.

Although the method for manufacturing the semiconductor device 10 is described above, the method for manufacturing the semiconductor device 10 is not limited thereto.

In the semiconductor device 10 according to the present embodiment, the thickness of the first silicon nitride insulating layer 110 in contact with the light shielding layer 105 is adjusted to a value based on predetermined conditions, so that photodegradation can be suppressed.

### Second Embodiment

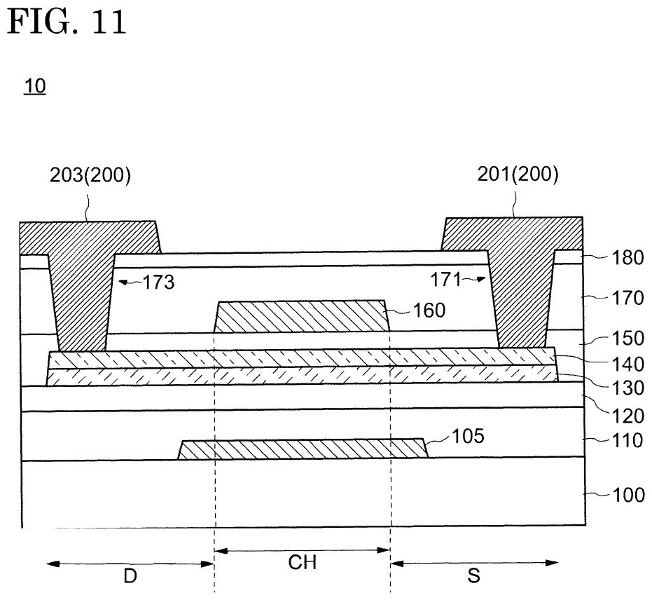

A semiconductor device 20 according to an embodiment of the present invention is described with reference to FIGS. 11 to 16. In addition, when the components of the semiconductor device 20 are similar to the components of the semiconductor device 10, the description of the components of the semiconductor device 20 may be omitted.

### [1. Configuration of Semiconductor Device 20]

A configuration of a semiconductor device 20 according to an embodiment of the present invention is described with reference to FIG. 11. FIG. 11 is a schematic cross-sectional view showing a configuration of the semiconductor device 20 according to an embodiment of the present invention. Specifically, FIG. 11 is a cross-sectional view cut along a line A-A′ in FIG. 2.

As shown in FIG. 11, the semiconductor device 10 includes the substrate 100, the light shielding layer 105, the first silicon nitride insulating layer 110, the first silicon oxide insulating layer 120, a metal oxide layer 130, the oxide semiconductor layer 140, the second silicon oxide insulating layer 150, the gate electrode 160, the second silicon nitride insulating layer 170, the third silicon oxide insulating layer 180, the source electrode 201, and the drain electrode 203. The metal oxide layer 130 is provided on the first silicon oxide insulating layer 120. The oxide semiconductor layer 140 is provided on the metal oxide layer 130. An edge surface of the metal oxide layer 130 is substantially aligned with the edge surface of the oxide semiconductor layer 140.

The metal oxide layer 130 can promote crystallization of the oxide semiconductor layer 140. Therefore, when the metal oxide layer 130 is provided, the oxide semiconductor layer 140 is likely to contain Poly-OS. For example, aluminum oxide (AlOₓ) or aluminum oxynitride (AlOₓN_{y}) can be used for the metal oxide layer 130.

### [2. Manufacturing Method of Semiconductor Device 20]

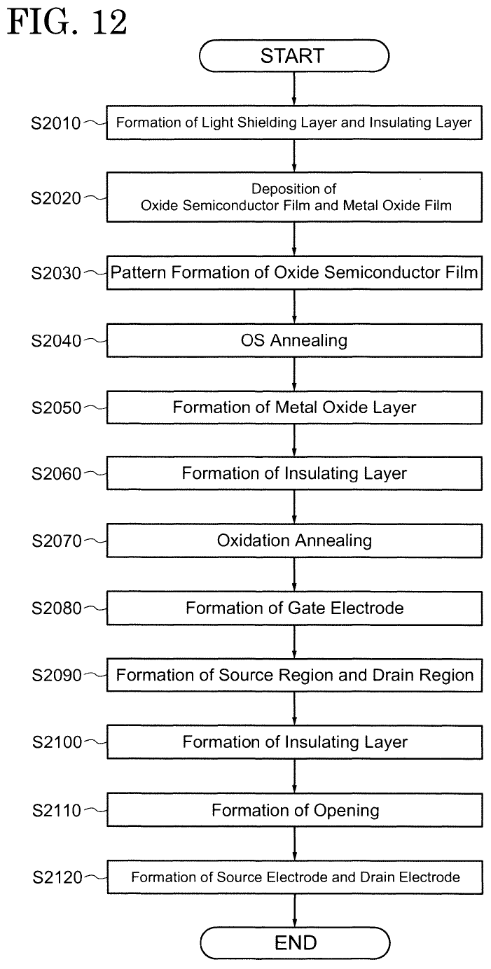

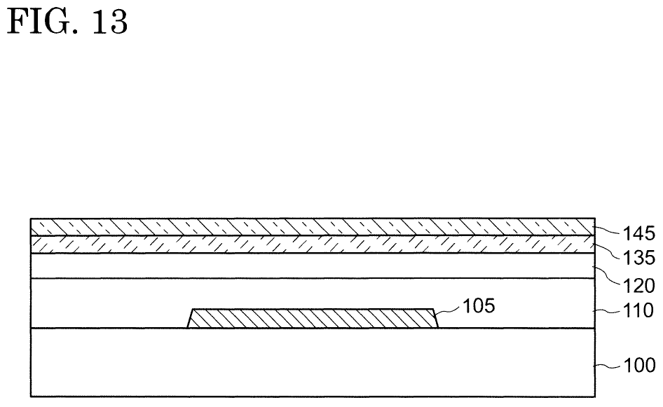

A method for manufacturing the semiconductor device 20 according to an embodiment of the present invention is described with reference to FIGS. 12 to 16. FIG. 12 is a flowchart showing a method for manufacturing the semiconductor device 20 according to an embodiment of the present invention. FIGS. 13 to 16 are schematic cross-sectional views showing a method for manufacturing the semiconductor device 20 according to an embodiment of the present invention. The method for manufacturing a semiconductor device 20 includes steps S2010 to S2120. Although steps S2010 to S2120 are described in order below, the order of the steps may be interchanged in the method for manufacturing a semiconductor device 20. Further, the method for manufacturing the semiconductor device 20 may include additional steps.

Since step S2010 is similar to step S1010, the description of step S2010 is omitted.

In step S2020, a metal oxide film 135 and an oxide semiconductor film 145 are sequentially deposited on the first silicon oxide insulating layer 120 (see FIG. 13). The metal oxide film 135 is deposited using a sputtering method. For example, the thickness of the metal oxide film 135 is greater than or equal to 1 nm and less than or equal to 10 nm, preferably greater than or equal to 1 nm and less than or equal to 5 nm. In addition, the oxide semiconductor film 145 deposited on the metal oxide film 135 is amorphous.

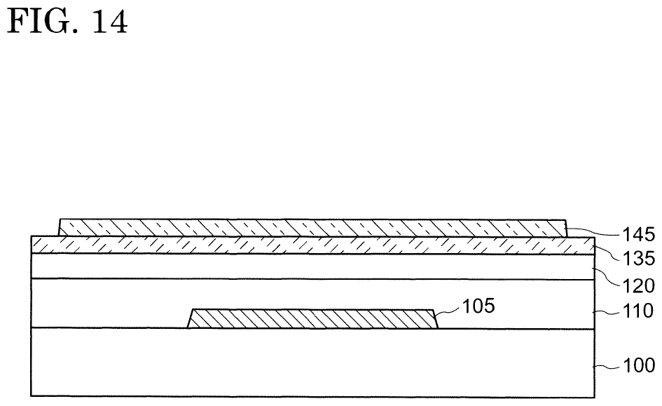

Step S2030 is similar to step S1030. That is, the oxide semiconductor film 145 is patterned (see FIG. 14).

Since step S2040 is similar to step S1040, the description of step S2040 is omitted.

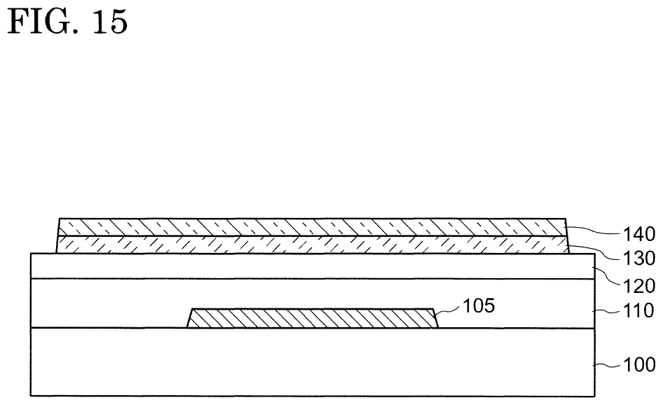

In step S2050, the metal oxide film 135 is patterned to form the metal oxide layer 130 (see FIG. 15). The oxide semiconductor layer 140 containing Poly-OS, which is sufficiently crystallized by OS annealing, has high etching resistance. Thus, even when the oxide semiconductor layer 140 containing Poly-OS is used as a mask when the metal oxide film 135 is patterned, the oxide semiconductor layer 140 does not disappear. Therefore, in the Poly-OS technology, the metal oxide layer 130 can be etched using the patterned oxide semiconductor layer 140 containing Poly-OS as a mask. When the metal oxide film 135 is etched using the oxide semiconductor layer 140 as a mask, a photolithography process can be omitted. In this case, the edge surface of the metal oxide layer 130 is substantially aligned with the edge surface of the oxide semiconductor layer 140. For the etching of the metal oxide film 135, wet etching may be used or dry etching may be used. For example, diluted hydrofluoric acid (DHF) is used for the wet etching.

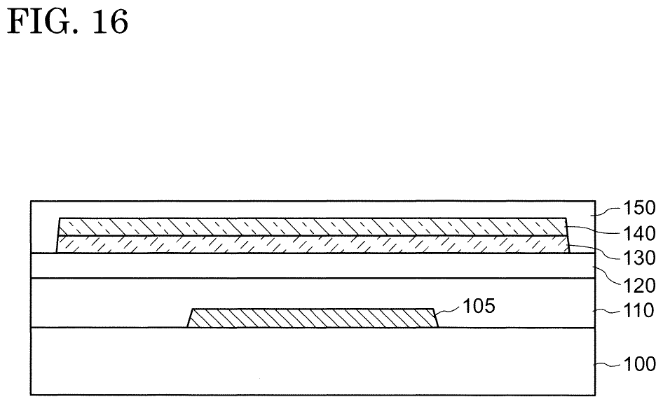

Step S2060 is similar to step S1050. That is, the second silicon oxide insulating layer 150 is formed so as to cover the upper surface and the edge surface of the oxide semiconductor layer 140 and the edge surface of the metal oxide layer 130 (see FIG. 16).

Since steps S2070 to S2120 are similar to steps S1060 to S1110, the description of steps S2070 to S2120 is omitted.

Although the method for manufacturing the semiconductor device 20 is described above, the method for manufacturing the semiconductor device 20 is not limited thereto.

In the semiconductor device 10 according to the present embodiment, the thickness of the first silicon nitride insulating layer 110 in contact with the light shielding layer 105 is adjusted to a value based on predetermined conditions, so that photodegradation can be suppressed.

### EXAMPLES

The semiconductor device 20 is described in further detail based on fabricated samples.

### [1. Fabrication of Samples]

The semiconductor device 20 was fabricated on a glass substrate using the manufacturing method described in the Second Embodiment. Specifically, a plurality of samples were fabricated with different thicknesses of the first silicon nitride insulating layer 110 (25 nm, 50 nm, 75 nm, 100 nm, 125 nm, 150 nm, 175 nm, 200 nm, 225 nm, 250 nm, 275 nm, and 300 nm) and the first silicon oxide insulating layer 120 (50 nm, 100 nm, and 200 nm). The fabrication conditions for the other layers were common between the samples, and the main materials and thickness in the fabrication conditions are shown in Table 2.

TABLE 2

| | |
|---|---|
| Light shielding layer 105 | MoW, 100 nm |
| Metal oxide layer 130 | AlOₓ, 3ₙₘ |
| Oxide semiconductor | Poly-OS, 15 nm |
| layer 140 | |
| Second silicon oxide | SiOₓ, 75ₙₘ |
| insulating layer 150 | |
| Gate electrode 160 | MoW (upper layer)/Ti |
| | (lower layer), |
| | 300 nm/10 nm |
| Second silicon nitride | SiNₓ, 300 nm |
| insulating layer 170 | |

### [2. Evaluation of Samples]

### [2-1. Electrical Characteristics]

The initial electrical characteristics of each sample were measured. The conditions for measuring the electrical characteristics are shown in Table 3. For the measurement of the electrical characteristics, a sample having a channel width W/channel length L=4.5 μm/3.0 μm was used. Further, the S value and the field effect mobility (the linear field effect mobility in the linear region) of each sample were calculated from the electrical characteristics.

TABLE 3

| | |
|---|---|
| Source-Drain | 0.1 V |
| voltage | |
| Gate voltage | −15 V to +15 V |
| Measurement | Room temperature, |
| environment | dark room |

### [2-2. NBTIS Test]

In order to evaluate the photodegradation of each sample, a negative bias temperature illumination stress (NBTIS) test was performed. In the NBTIS test, the semiconductor device 20 was irradiated with light for a predetermined time, and the photodegradation of the semiconductor device 20 can be evaluated according to the magnitude of change in the threshold voltage of the semiconductor device 20 before and after the light irradiation. Specifically, when the photodegradation of the semiconductor device 20 is large, the variation amount in the threshold voltage of the semiconductor device 20 also becomes large. The conditions for the light irradiation in the NBTIS test are shown in Table 4. In the NBTIS test, a sample having a channel width W/channel length L=4.5 μm/3.0 μm was used, and the electrical characteristics of the sample after the light irradiation were measured under the measurement conditions shown in Table 3.

TABLE 4

| | |
|---|---|
| Light irradiation | From the gate electrode 160 |
| direction | to the oxide semiconductor |
| | layer 140 |
| Light source | White LED |
| Light intensity | 7000 lx |
| Temperature | 85° C. |
| Gate voltage | −20 V |
| Source voltage, | 0 V |
| Drain voltage | |
| Irradiation time | 1000 seconds |

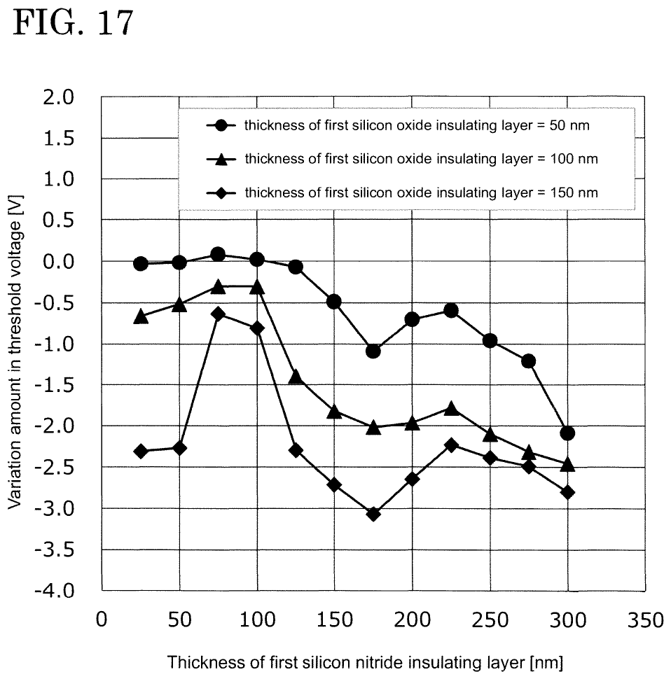

FIG. 17 is a graph showing the variation amount in the threshold voltage in the NBTIS test with respect to the thickness of the first silicon nitride insulating layer 110 and the thickness of the first silicon oxide insulating layer 120. The horizontal axis of FIG. 17 shows the thickness of the first silicon nitride insulating layer 110, and the vertical axis of FIG. 17 shows the variation amount in a threshold voltage in the NBTIS test. In FIG. 17, the plotted points for each thickness of the first silicon oxide insulating layer 120 are connected.

As shown in FIG. 17, the variation amount in a threshold voltage of semiconductor device 20 shows a periodic tendency with respect to the thickness of first silicon nitride insulating layer 110. More specifically, in the semiconductor device 20, the variation amount in a threshold voltage decreases for every 150 nm of the thickness of the first silicon nitride insulating layer 110. Further, the variation amount in a threshold voltage of the semiconductor device 20 does not depend on the thickness of the first silicon oxide insulating layer 120.

Since the periodicity of the variation amount in the threshold voltage of the semiconductor device 20 shown in FIG. 17 depends on the thickness of the first silicon nitride insulating layer 110, it is considered that the optical interference effect occurs due to the thickness of the first silicon nitride insulating layer 110. Thus, in order to investigate the influence of the optical interference effect by the first silicon nitride insulating layer 110, a simulation of a reflectance when an incidence angle of (angle from the normal direction of the second interface) of the light incident on the first silicon nitride insulating layer 110 was performed. In the simulation, an element consisting of the first silicon oxide insulating layer 120/the first silicon nitride insulating layer 110/the light shielding layer 105/the glass was used, and calculations were performed assuming that the incident light of a wavelength of 400 to 500 nm is reflected at the first interface and the second interface. In addition, since the thickness dependence of the first silicon oxide insulating layer 120 is not observed as shown in FIG. 17, the calculations were performed assuming that the light is incident from the first silicon oxide insulating layer 120. In other words, the calculations were performed assuming that the thickness of the first silicon oxide insulating layer 120 was infinite.

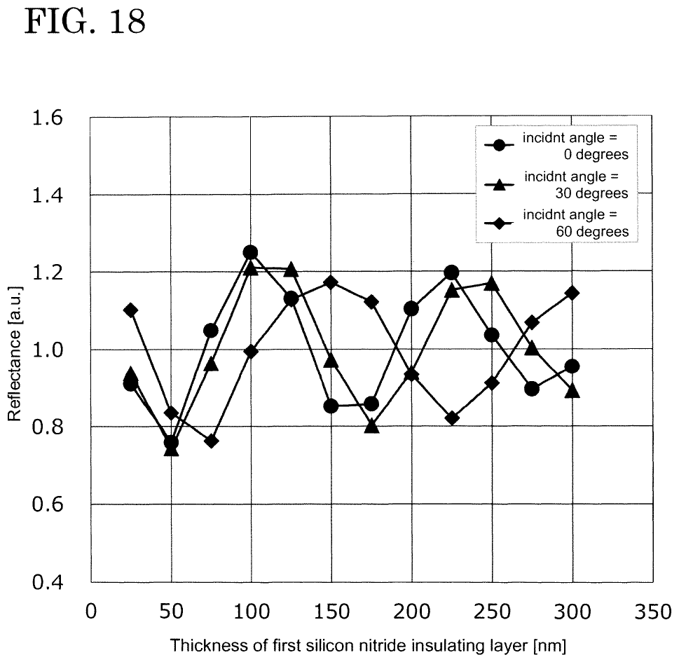

FIG. 18 shows the simulation result of the reflectance showing the incidence angle dependence of the first silicon nitride insulating layer 110. FIG. 18 shows the reflectance at incidence angles of 0 degrees, 30 degrees, and 60 degrees.

As shown in FIG. 18, the periodicity of the reflectance is observed at all of the incident angles of 0 degrees, 30 degrees, and 60 degrees. Further, as the incident angle changes from 0 degrees to 60 degrees, the period of the periodicity of the reflectance increases. In particular, the period when the incident angle is 60 degrees is 150 nm, which coincides with the period of the variation amount in the threshold voltage in the NBTIS test shown in FIG. 17. Specifically, the reflectance becomes minimum when the thickness of the first silicon nitride insulating layer 110 is about 75 nm and about 225 nm in FIG. 18, and the variation amount in the threshold voltage becomes minimum when the thickness of the first silicon nitride insulating layer 110 is about 75 nm and about 225 nm also in FIG. 17.

The above results show that the variation amount in the threshold voltage in the NBTIS test can be suppressed by adjusting the thickness of the first silicon nitride insulating layer 110 so that the reflectance of light with a wavelength of 450 nm incident on the second interface at 60 degrees is minimized. That is, when the thickness of the first silicon nitride insulating layer 110 satisfies the condition that the light reflected at the first interface and the light reflected at the second interface weaken each other when light with a wavelength of 450 nm is incident on the first silicon nitride insulating layer at 60 degrees from the normal direction of the second interface, photodegradation of the semiconductor device 20 can be suppressed.

For example, based on the present example, the thickness t (nm) of the first silicon nitride insulating layer 110 is adjusted to satisfy t=150 (a−1)+b (where a is a natural number and b is a constant). Here, the constant b is, for example, 75±12.5. The value±12.5 of the constant b is an error, and corresponds to ½ of 25 nm, which is the number of steps in the measurement or simulation. In this way, the error may be calculated from the number of steps.

Although the evaluation using the sample of the semiconductor device 20 is described in the present example, the semiconductor device 10 can be evaluated in a similar manner.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a light shielding layer;
a first silicon nitride insulating layer over and in contact with the light shielding layer;
a first silicon oxide insulating layer over and in contact with the first silicon nitride layer;
an oxide semiconductor layer comprising a channel region, a source region, and a drain region, over the first silicon oxide insulating layer;
a second silicon oxide insulating layer over the oxide semiconductor layer;
a gate electrode over the second silicon oxide insulating layer; and
a second silicon nitride insulating layer over the gate electrode,
wherein a first interface is formed between the light shielding layer and the first silicon nitride insulating layer,
a second interface is formed between the first silicon nitride insulating layer and the first silicon oxide insulating layer,
in a plan view, the entire channel region overlaps the light shielding layer,
the first silicon oxide insulating layer is in contact with the second silicon oxide insulating layer, and
a thickness t of the first silicon nitride layer satisfies a condition in which first light reflected at the first interface and second light reflected at the second interface weaken each other when light having a wavelength of 450 nm is incident on the first silicon nitride insulating layer at an angle of 60 degrees from a normal direction of the second interface.

2. The semiconductor device according to claim 1, wherein the thickness of the first silicon nitride insulating layer satisfies t=150 (a−1)+b (where a is a natural number and b is a constant).

3. The semiconductor device according to claim 2, wherein the constant b is 75±12.5.

4. The semiconductor device according to claim 1, wherein a thickness of the first silicon oxide insulating layer is greater than the thickness t of the first silicon nitride insulating layer.

5. The semiconductor device according to claim 1, wherein a total thickness of the first silicon oxide insulating layer and the second silicon oxide insulating layer is greater than the thickness t of the first silicon nitride insulating layer.

6. The semiconductor device according to claim 1, further comprising a metal oxide layer between the first silicon oxide insulating layer and the oxide semiconductor layer.

7. The semiconductor device according to claim 6, wherein an edge surface of the metal oxide layer is substantially aligned with an edge surface of the oxide semiconductor layer.

8. The semiconductor device according to claim 6, wherein a thickness of the metal oxide layer is less than or equal to 5 nm.

9. The semiconductor device according to claim 6, wherein the metal oxide layer comprises aluminum oxide.

10. The semiconductor device according to claim 1,
wherein the oxide semiconductor layer comprises a plurality of metal elements,
the plurality of metal elements comprises indium, and
an atomic ratio of the indium to the plurality of metal elements is greater than or equal to 50%.

11. The semiconductor device according to claim 1, wherein the oxide semiconductor layer has a polycrystalline structure.

12. The semiconductor device according to claim 1, wherein each of the source region and the drain region comprises one element selected from the group consisting of boron, phosphorus, argon, and nitrogen.
